(19) United States
(12) Patent Application Publication
(10) Pub. No.: US 2025/0160126 A1
(43) Pub. Date: May 15, 2025

(54) DISPLAY DEVICE AND METHOD OF FABRICATING THE SAME

(71) Applicant: Samsung Display Co., LTD., Yongin-si (KR)

(72) Inventors: Sang Duk LEE, Yongin-si (KR); Hoi Kwan LEE, Yongin-si (KR)

(73) Assignee: Samsung Display Co., LTD., Yongin-si (KR)

(21) Appl. No.: 18/731,866

(22) Filed: Jun. 3, 2024

(30) Foreign Application Priority Data
Nov. 9, 2023 (KR) 10-2023-0154042

(51) Int. Cl. H10K 59/122; H10K 59/12; H10K 59/80; H10K 71/00

(52) U.S. Cl. CPC H10K 59/122; H10K 59/1201; H10K 59/873; H10K 59/8792; H10K 71/851

(57) ABSTRACT

A display device comprises a substrate; a first electrode on the substrate; a pixel-defining layer on the first electrode; an emissive layer on the first electrode and the pixel-defining layer; a second electrode on the emissive layer; an encapsulation layer on the second electrode; a functional layer on the encapsulation layer; and a reinforcement layer between the encapsulation layer and the functional layer, wherein an interface between the reinforcement layer and the functional layer is substantially flat.

### CROSS REFERENCE TO RELATED APPLICATION(S)

This application claims priority to and benefits of Korean Patent Application No. 10-2023-0154042 under 35 U.S.C. § 119, filed on Nov. 9, 2023 in the Korean Intellectual Property Office (KIPO), the disclosure of which is incorporated herein by reference in its entirety.

### BACKGROUND

### 1. Technical Field

The disclosure relates to a display device, and more particularly, to a display device that can improve adhesion between a reinforcement layer and a functional layer, and a method of fabricating the same.

### 2. Description of the Related Art

A variety of electronic devices that provide multimedia, such as televisions, mobile phones, navigation systems, computer monitors and game consoles, are being developed. Electronic devices include a display panel that displays images. In particular, a variety of portable electronic devices such as mobile phones and tablet PCs are currently under development. Additionally, display devices that work with portable electronic devices are under development.

### SUMMARY

Aspects of the disclosure provide a display device that can improve adhesion between a reinforcement layer and a functional layer, and a method of fabricating the same.

The technical objectives to be achieved by the disclosure are not limited to those described herein, and other technical objectives that are not mentioned herein would be clearly understood by a person skilled in the art from the description of the disclosure

According to an embodiment of the disclosure, a display device comprises a substrate; a first electrode on the substrate; a pixel-defining layer on the first electrode; an emissive layer on the first electrode and the pixel-defining layer; a second electrode on the emissive layer; an encapsulation layer on the second electrode; a functional layer on the encapsulation layer; and a reinforcement layer between the encapsulation layer and the functional layer, wherein an interface between the reinforcement layer and the functional layer is substantially flat.

In an embodiment, the reinforcement layer may contain hydrofluoric acid.

In an embodiment, a first side surface of the reinforcement layer may contain the hydrofluoric acid.

In an embodiment, the display device may further comprise a display driver disposed in a pad area on the substrate.

In an embodiment, the first side surface of the reinforcement layer may be adjacent to the display driver.

In an embodiment, a second side surface of the reinforcement layer located opposite to the first side surface of the reinforcement layer may comprise a carbonization region.

In an embodiment, the reinforcement layer may be made of a material containing at least one of an optically transparent resin, epoxy, and urethane.

In an embodiment, the functional layer may comprise a polarizer.

In an embodiment, the display device may further comprise an auxiliary functional layer on the functional layer.

In an embodiment, the auxiliary functional layer may comprise at least one of an anti-fingerprint layer, an anti-reflection layer, and a hard coating layer.

In an embodiment, the display device may further comprise a window layer between the functional layer and the auxiliary functional layer.

In an embodiment, the display device may further comprise an intermediate board connected to a pad area of the substrate.

In an embodiment, the display device may further comprise a circuit board connected to the intermediate board.

In an embodiment, the display device may further comprise a protective layer disposed under the substrate.

According to an embodiment of the disclosure, a method of fabricating a display device comprises disposing an encapsulation layer on a base substrate; disposing a first mask on a pad area of the base substrate to cover the pad area; disposing a base reinforcement layer on an entire surface of the base substrate comprising the encapsulation layer and the first mask; disposing a second mask on the base reinforcement layer in line with the encapsulation layer; patterning the base reinforcement layer by selectively removing a portion of the base reinforcement layer exposed by the second mask; removing the first mask and the second mask; and cutting the base substrate and the base reinforcement layer along a scribing line to form a display panel comprising a substrate and a reinforcement layer.

In an embodiment, the patterning of the base reinforcement layer by selectively removing the portion of the base reinforcement layer exposed by the second mask may comprise selectively removing the portion of the base reinforcement layer to expose the first mask.

In an embodiment, the patterning of the base reinforcement layer by selectively removing the portion of the base reinforcement layer exposed by the second mask may comprise etching the base reinforcement layer using an etchant.

In an embodiment, the etchant may contain hydrofluoric acid.

In an embodiment, the cutting of the base substrate and the base reinforcement layer along the scribing line comprises cutting the base substrate and the base reinforcement layer using laser beam.

In an embodiment, the display device may further comprise disposing a functional layer on the reinforcement layer of the display panel.

In an embodiment, the functional layer may comprise a polarizer.

In an embodiment, the display device may further comprise disposing an auxiliary functional layer on the functional layer.

In an embodiment, the auxiliary functional layer may comprise at least one of an anti-fingerprint layer, an anti-reflection layer, and a hard coating layer.

In an embodiment, the display device may further comprise disposing a window layer between the functional layer and the auxiliary functional layer.

According to an embodiment of the disclosure, a base reinforcement layer may be formed on the entire surface of a base substrate and then the base substrate may be cut in a display device. Accordingly, the upper surface of the reinforcement layer of the display panel may have a substantially flat surface. Therefore, the adhesion between the functional layer and the reinforcement layer can be improved.

According to an embodiment of the disclosure, a base reinforcement layer may be formed on the entire surface of a base substrate and then the base substrate may be cut in a display device, so that a display device can be fabricated faster compared to a process of forming a reinforcement layer for each display panel after the cutting process.

The effects according to the embodiments of the disclosure are not limited to those mentioned above and more various effects are included in the following description of the disclosure.

### BRIEF DESCRIPTION OF THE DRAWINGS

The above and other aspects and features of the disclosure will become more apparent by describing in detail embodiments thereof with reference to the attached drawings, in which:

FIG. 1 is a schematic cross-sectional view of a display device according to an embodiment of the disclosure.

FIGS. 2 to 20 are schematic views for illustrating a method of fabricating a display device according to an embodiment of the disclosure.

FIG. 21 is a schematic cross-sectional view taken along line VIII-VIII′ of FIG. 16.

FIG. 22 is a schematic cross-sectional view taken along line IX-IX′ of FIG. 16.

FIG. 23 is a schematic view for illustrating a method of fabricating a display device according to an embodiment of the disclosure.

FIG. 24 is a schematic view for illustrating a method of fabricating a display device according to an embodiment of the disclosure.

FIG. 25 is a schematic cross-sectional view of a display device according to the embodiment of the disclosure.

FIG. 26 is a schematic cross-sectional view of a display device according to an embodiment of the disclosure.

### DETAILED DESCRIPTION OF THE EMBODIMENTS

Advantages and features of the disclosure and methods to achieve them will become apparent from the descriptions of embodiments hereinbelow with reference to the accompanying drawings. However, the disclosure is not limited to embodiments disclosed herein but may be implemented in various different ways. The embodiments are provided for making the disclosure of the disclosure thorough and for conveying the scope of the disclosure to those skilled in the art. It is to be noted that the scope of the disclosure is defined only by the claims.

As used herein, a phrase “an element A on an element B” refers to that the element A may be disposed directly on the element B and/or the element A may be disposed indirectly on the element B via another element C. Like reference numerals/characters may denote like elements throughout the descriptions. The figures, dimensions, ratios, angles, numbers of elements given in the drawings are merely illustrative and are not limiting.

Although terms such as first, second, etc. are used to distinguish arbitrarily between the elements such terms describe, and thus these terms are not necessarily intended to indicate temporal or other prioritization of such elements. These terms are used to merely distinguish one element from another. Accordingly, as used herein, a first element may be a second element within the technical scope of the disclosure.

Features of various embodiments of the disclosure may be combined partially or totally. As will be clearly appreciated by those skilled in the art, technically various interactions and operations are possible. Various embodiments can be practiced individually or in combination. When an element is referred to as being “on,” “connected to,” or “coupled to” another element, it may be directly on, connected to, or coupled to the other element or intervening elements or layers may be present. When, however, an element is referred to as being “directly on,” “directly connected to,” or “directly coupled to” another element, there are no intervening elements or layers present. To this end, the term “connected” may refer to physical, electrical, and/or fluid connection, with or without intervening elements.

The term “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

The term “and/or” includes all combinations of one or more of which associated configurations may define. For example, “A and/or B” may be understood to mean “A, B, or A and B.”

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

Hereinafter, embodiments of the disclosure will be described in detail with reference to the accompanying drawings.

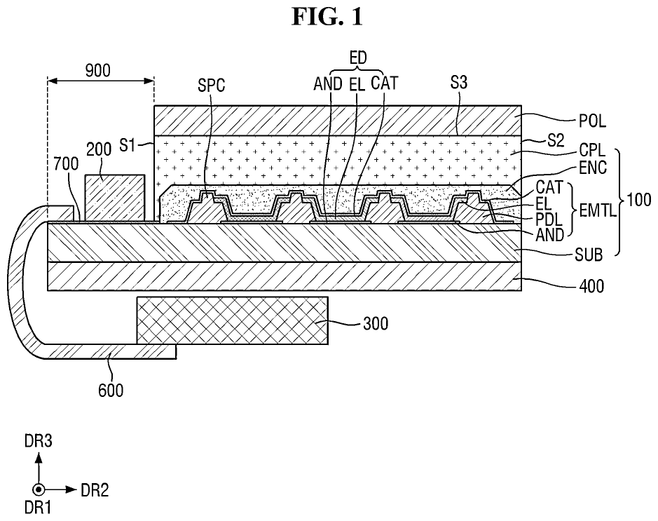

FIG. 1 is a schematic cross-sectional view of a display device according to an embodiment of the disclosure.

As shown in FIG. 1, a display device according to an embodiment may include a display panel 100, a display driver 200, an intermediate board 600, a circuit board 300, and/or a functional layer POL.

The display panel 100 may include a substrate SUB, an emission material layer EMTL, an encapsulation layer ENC, and/or a reinforcement layer CPL disposed in the third direction DR3. Although not shown in the drawings, the display panel 100 may further include a transistor layer disposed between the substrate SUB and the emission material layer EMTL, a touch sensing unit (or touch sensing part) disposed on the encapsulation layer ENC, and a color filter layer disposed on the touch sensing unit.

A protective layer 400 may be disposed under the display panel 100. For example, the protective layer 400 may be disposed under the substrate SUB. In other words, the protective layer 400 may be disposed on the opposite side of the functional layer POL with the display panel 100 therebetween. The protective layer 400 can prevent outside light from being incident on the display panel 100. The protective layer 400 can prevent external shock from being transmitted to the lower portion of the display panel 100. The protective layer 400 may be implemented as a film.

The substrate SUB may be disposed on the protective layer 400. The substrate SUB may be a flexible substrate that can be bent, folded, or rolled. For example, the substrate SUB may include, but is not limited to, a polymer resin such as polyimide PI. For another example, the substrate SUB may include a glass material or a metal material.

The transistor layer may be disposed on the substrate SUB. The transistor layer may include one or more thin-film transistors forming pixel circuits of the pixels. The transistor layer may further include gate lines, data lines, voltage lines, gate control lines, fan-out lines for connecting the display driver with the data lines, and/or lead lines for connecting the display driver with pads. Each of the transistors may include a semiconductor region, a source electrode, a drain electrode, and a gate electrode. For example, in case that the gate driver is formed on a side of the non-display area of the display panel 100, the gate driver may include thin-film transistors.

The transistor layer may be disposed in a display area and the non-display area of the substrate. The thin-film transistors in each of the pixels, the gate lines, the data lines and/or the voltage lines in the transistor layer may be disposed in the display area. The gate control lines and the fan-out lines of the transistor layer may be disposed in the non-display area.

The emission material layer EMTL may be disposed on the thin-film transistor layer. The emission material layer EMTL may include one or more light-emitting elements ED in each of which a first electrode AND, an emissive layer EL and a second electrode CAT are stacked on one another sequentially to emit light, and a pixel-defining layer PDL for defining the pixels. The light-emitting elements ED in the emission material layer EMTL may be disposed in the display area of the substrate SUB. According to an embodiment of the disclosure, the pixel-defining layer PDL may further include spacers SPC protruding from the top of the pixel-defining layer PDL in the third direction DR3. The pixel-defining layer PDL and the spacers SPC may be formed integrally or integral with each other. The spacers SPC may support a mask (e.g., a fine metal mask) used for forming the emissive layer EL.

The emissive layer EL may be, for example, an emissive layer EL containing an organic material. The emissive layer EL may include a hole transporting layer, an organic light-emitting layer and an electron transporting layer. In case that the first electrode AND receives a voltage (e.g., data voltage) and the second electrode CAT receives a common voltage (e.g., cathode voltage) through the thin-film transistors in the thin-film transistor layer, holes and electrons may move to the organic emissive layer EL through the hole transporting layer and the electron transporting layer, respectively, such that they combine in the organic emissive layer EL to emit light. For example, the first electrode AND may be an anode electrode while the second electrode CAT may be a cathode electrode. It is, however, to be understood that the disclosure is not limited thereto.

As another example, examples of the light-emitting elements ED may include quantum-dot light-emitting diodes each including a quantum-dot emissive layer, inorganic light-emitting diodes each including an inorganic semiconductor, or micro light-emitting diodes.

The encapsulation layer ENC may cover the upper and side surfaces of the emission material layer EMTL, and can protect the emission material layer EMTL. The encapsulation layer ENC may include at least one inorganic layer and/or at least one organic layer for encapsulating the emission material layer EMTL.

The touch sensing unit may be disposed on the encapsulation layer ENC. The touch sensing layer may include one or more touch electrodes for sensing a user's touch by capacitive sensing, and touch lines connecting the touch electrodes with a touch driver. For example, the touch sensing layer may sense a user's touch by mutual-capacitance sensing or self-capacitance sensing.

The display driver 200 may output signals and voltages for driving the display panel 100. The display driver 200 may supply data voltages to data lines. The display driver 200 may apply a supply voltage to a voltage line and may supply gate control signals to the gate driver. The display driver 200 may be implemented as an integrated circuit (IC) and may be attached on the display panel 100 by a chip-on-glass (COG) technique, a chip-on-plastic (COP) technique, or ultrasonic bonding. For example, the display driver 200 may be disposed in the non-display area of the substrate SUB. For example, the display driver may be disposed in a pad area 900 (or mounting area) in the non-display area.

The intermediate board 600 may physically and electrically connect the substrate SUB of the display panel 100 with the circuit board 300. For example, a side of the intermediate board 600 may be physically and electrically connected to the pad area 900 of the display panel 100, and the other side of the intermediate board 600 may be physically and electrically connected to the circuit board 300. The intermediate board may be bent into a U-shape.

A side of the intermediate board 600 may be connected to the substrate SUB through a first conductive adhesive member. For example, a side of the intermediate board 600 may be connected to a pad electrode 700 disposed in the pad area 900 of the substrate SUB through the first conductive adhesive member. The pad electrode 700 of the substrate SUB may also be connected to the display driver 200 described above. Accordingly, the intermediate board 600 and the display driver 200 may be electrically connected to each other. The first conductive adhesive member may be, for example, an anisotropic conductive film (ACF).

According to an embodiment of the disclosure, the intermediate board 600 may be, for example, a flexible printed circuit board (FPCB), a printed circuit board (PCB), or a flexible film such as a chip-on-film (COF).

Another side of the intermediate board 600 may be connected to the circuit board 300 through a second conductive adhesive member. For example, the other side of the intermediate board 600 may be connected to the circuit board 300 through the second conductive adhesive member. Accordingly, the circuit board 300, the intermediate board 600 and the display driver 200 may be electrically connected with one another. The second conductive adhesive member may be, for example, an anisotropic conductive film (ACF).

According to an embodiment of the disclosure, the circuit board 300 may be, for example, a flexible printed circuit board (FPCB), a printed circuit board (PCB), or a flexible film such as a chip-on-film (COF).

The circuit board 300 may be placed below the protective layer 400. For example, circuit elements such as a touch driver and a power supply unit (or power supply) may be disposed on the circuit board 300. For example, the touch driver and the power supply unit may be mounted on the circuit board 300. The circuit elements (e.g., at least one of the touch driver and the power supply unit) of the circuit board 300 may be electrically connected to the display driver 200 and the display panel 100 on the substrate SUB through the circuit board 300 and the intermediate board 600.

The touch driver may be electrically connected to the touch sensing unit of the display panel 100. The touch driver may provide touch driving signals to one or more touch electrodes of the touch sensing unit and may sense a change in the capacitance between the touch electrodes. For example, the touch driving signals may be pulse signals having a frequency (e.g., a predetermined or selectable frequency). The touch driver may determine whether there is an input and may find the coordinates of the input based on the amount of the change in the capacitance between the touch electrodes. The touch driver may be implemented as an integrated circuit (IC).

The power supply unit may apply supply voltages to the display driver 200 and the display panel 100. The power supply unit may generate a driving voltage to supply it to a driving voltage line, may generate an initialization voltage to supply it to an initialization voltage line, and may generate a common voltage to supply it to a second electrode CAT shared by the light-emitting elements ED of one or more pixels For example, the driving voltage may be a high-level voltage for driving the light-emitting element ED, and the common voltage may be a low-level voltage for driving the light-emitting element ED.

The reinforcement layer CPL may be disposed on the encapsulation layer ENC. For example, the reinforcement layer CPL may be disposed between the encapsulation layer ENC and the functional layer POL. The reinforcement layer CPL may be in contact with the encapsulation layer ENC and the functional layer POL. The reinforcement layer CPL can protect the display panel 100 from, for example, external shock. For example, the reinforcement layer CPL may be made of (or include) a material containing an optically transparent resin that has high strength and flexibility. According to an embodiment of the disclosure, the reinforcement layer CPL may be made of a material containing at least one of epoxy and urethane.

According to an embodiment of the disclosure, the interface between the reinforcement layer CPL and the functional layer POL may be substantially flat. For example, the top surface of the reinforcement layer may be flat.

According to an embodiment of the disclosure, the reinforcement layer CPL may include at least one of hydrofluoric acid and carbonization regions. For example, a first side surface S1 of the reinforcement layer CPL may be disposed adjacent to the display driver 200, and thus the first side surface S1 may contain hydrofluoric acid. A second side surface S2 of the reinforcement layer CPL is opposite to the first side surface S1, and the second side S2 may contain a carbonization region. The carbonization region may be a blackened portion. According to an embodiment, at least one of other surfaces that is adjacent to the second side surface S2 of the reinforcement layer CPL in the first direction DR1 and/or the second direction DR2 and is connected to the second side surface S2 may have the carbonization region described above.

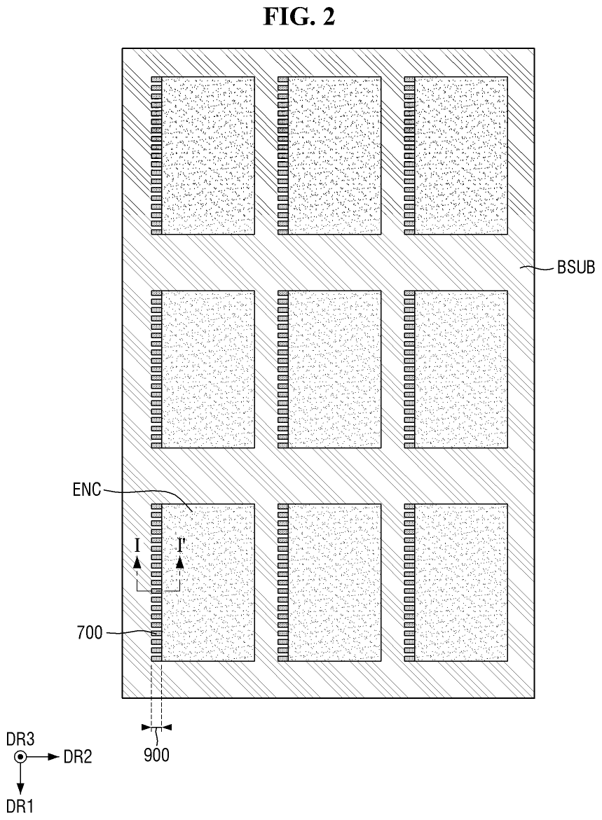

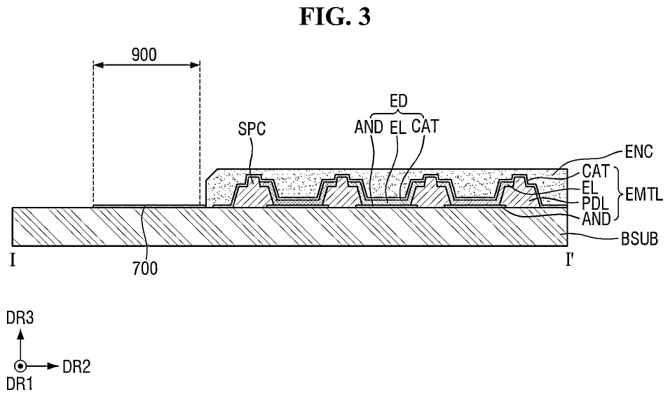

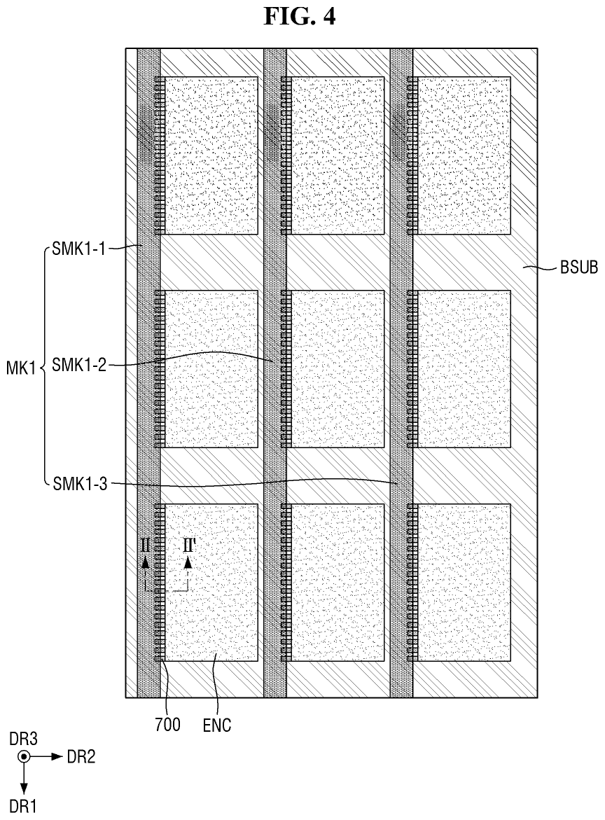

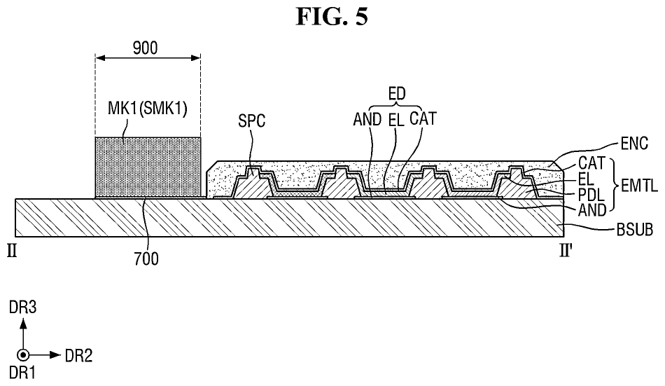

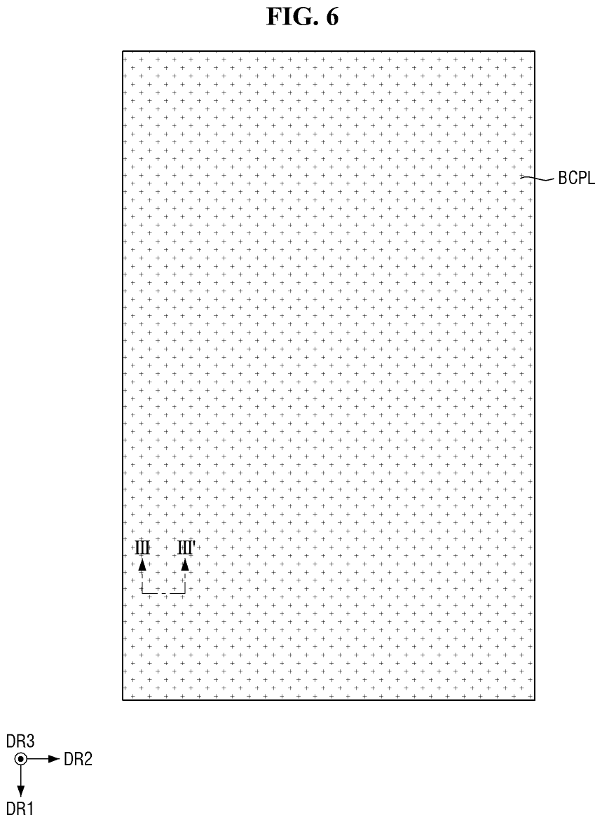

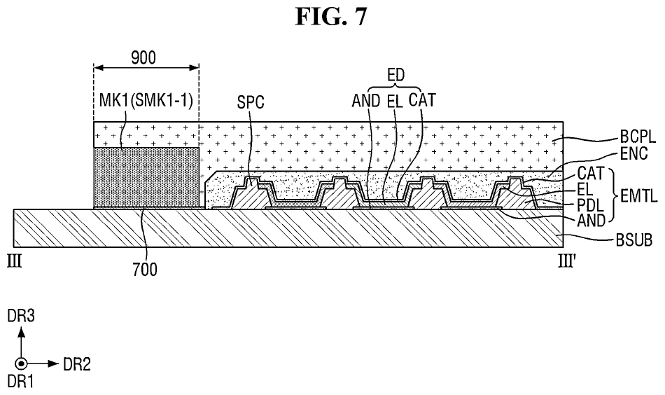

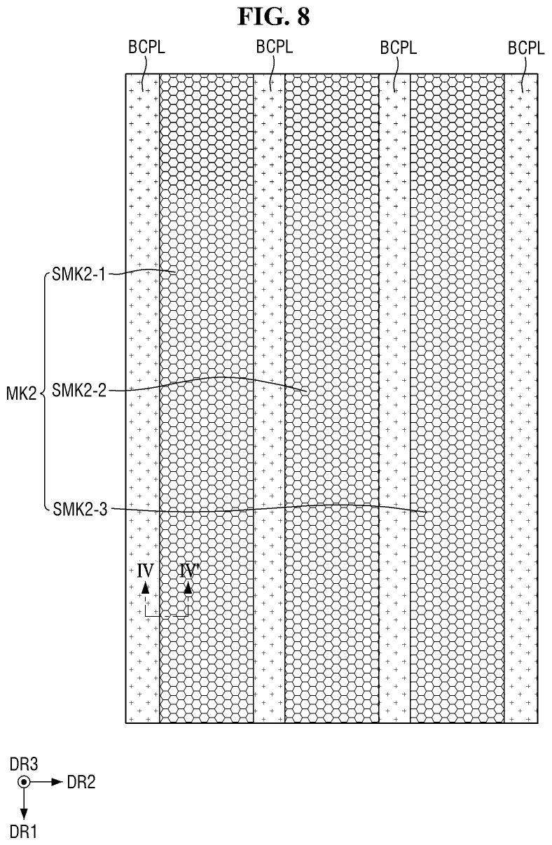

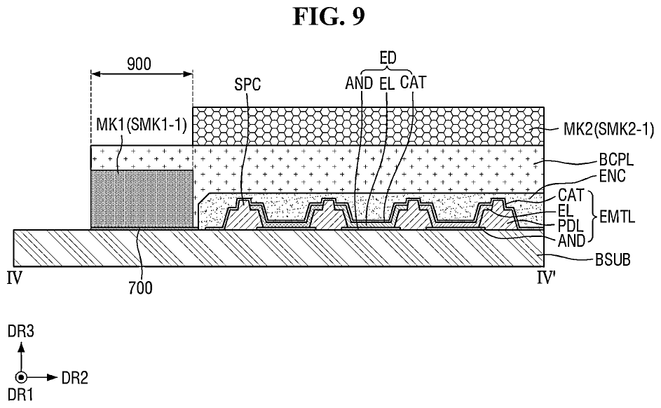

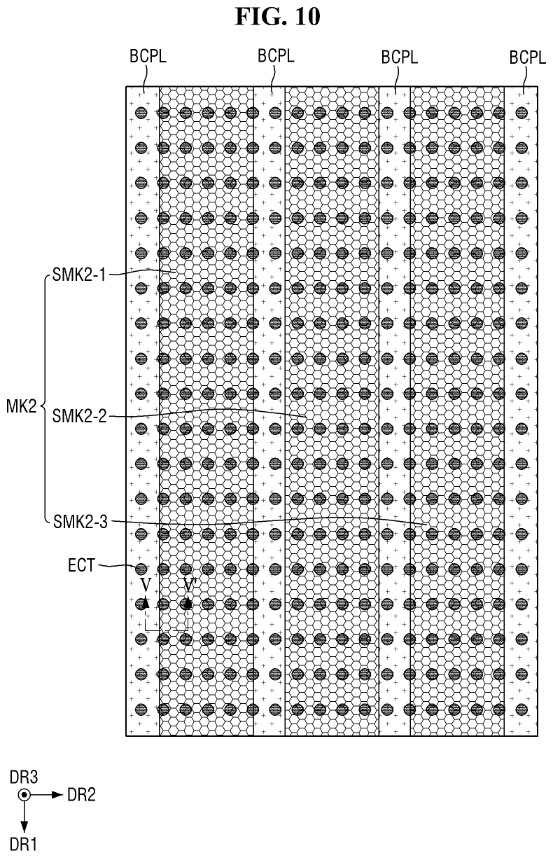

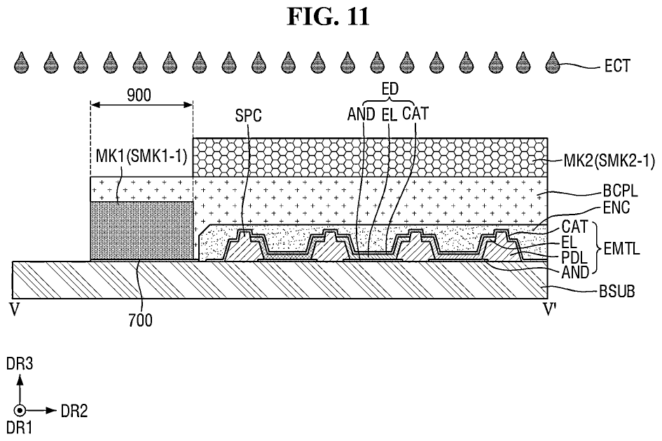

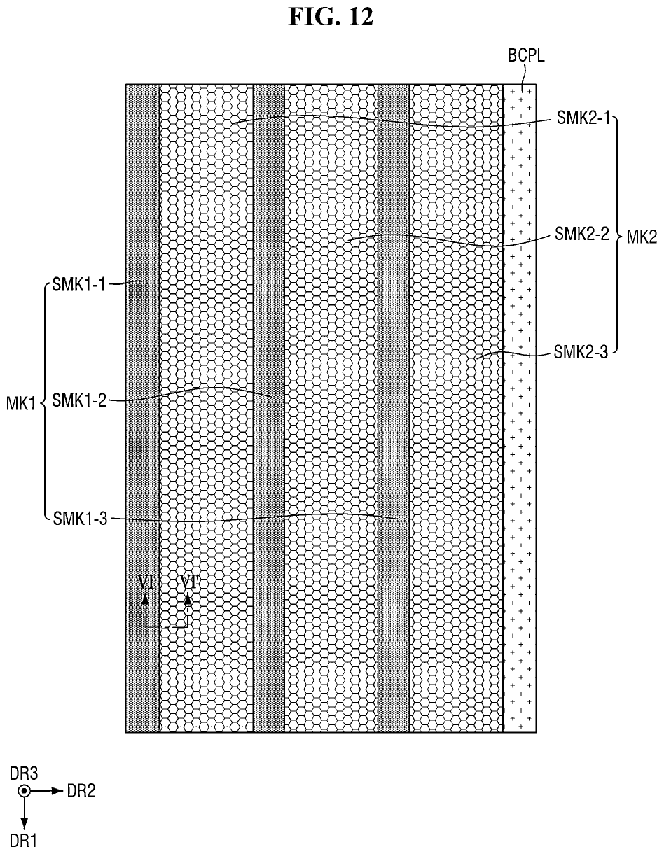

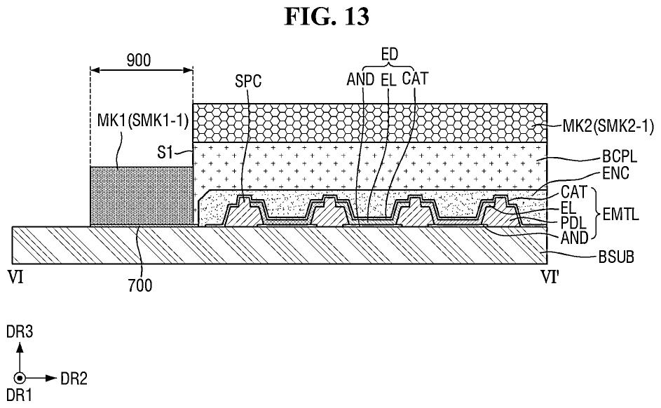

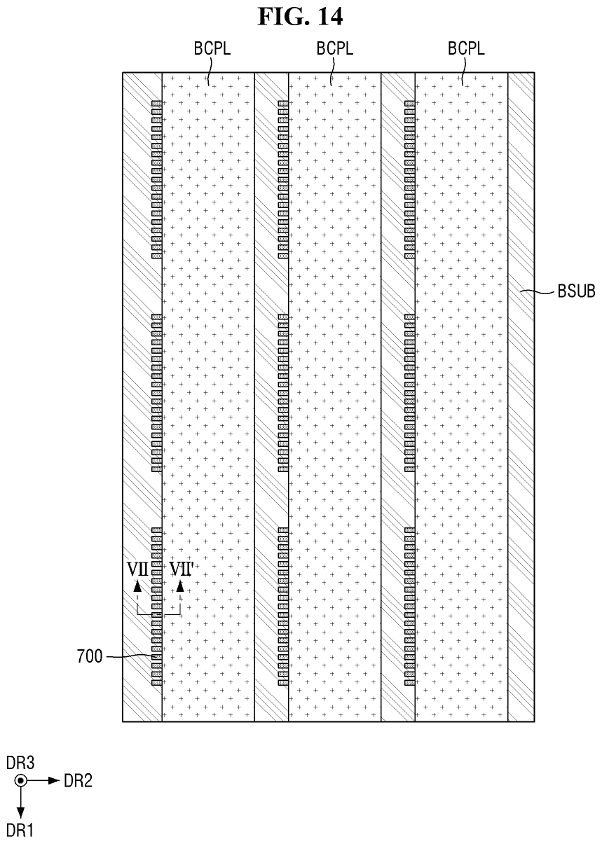

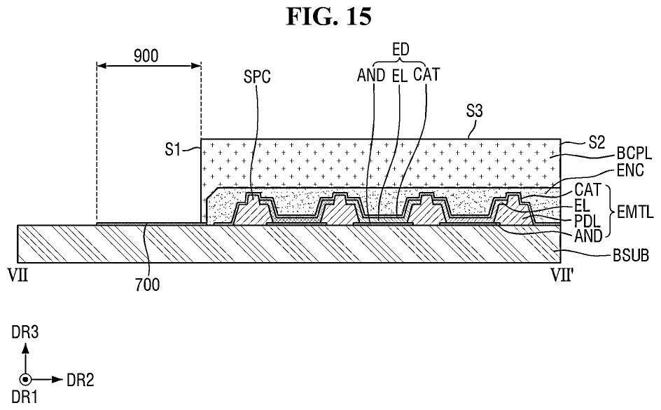

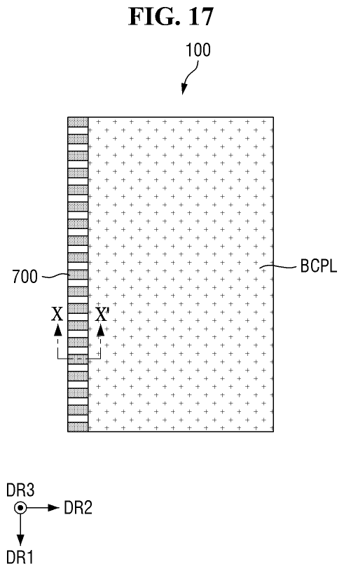

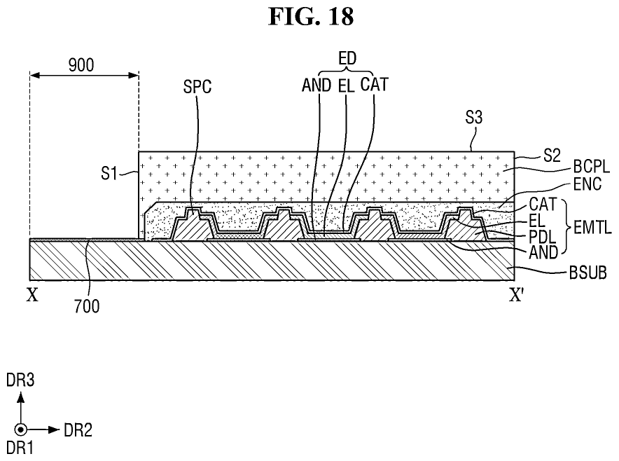

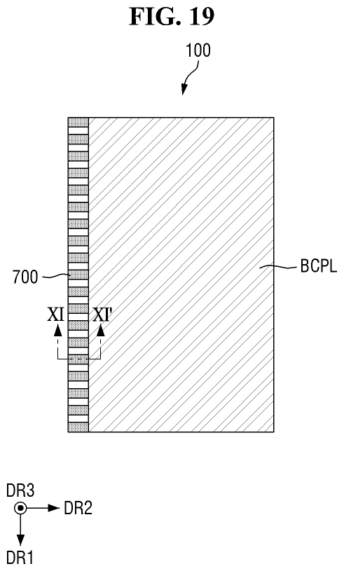

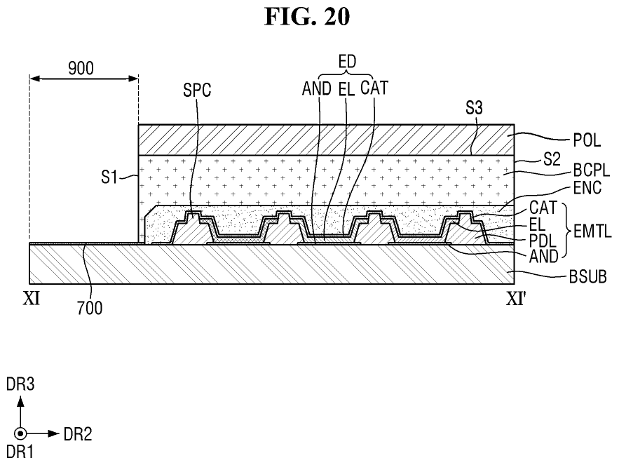

FIGS. 2 to 20 are schematic views for illustrating a method of fabricating a display device according to an embodiment of the disclosure. FIG. 3 is a schematic cross-sectional view taken along line I-I′ of FIG. 2. FIG. 5 is a schematic cross-sectional view taken along line II-II′ of FIG. 4. FIG. 7 is a schematic cross-sectional view taken along line III-III′ of FIG. 6. FIG. 9 is a schematic cross-sectional view taken along line IV-IV′ of FIG. 8. FIG. 11 is a schematic cross-sectional view taken along line V-V′ of FIG. 10. FIG. 13 is a schematic cross-sectional view taken along line VI-VI′ of FIG. 12. FIG. 15 is a schematic cross-sectional view taken along line VIII-VIII′ of FIG. 14. FIG. 18 is a schematic cross-sectional view taken along line X-X′ of FIG. 17. FIG. 20 is a schematic cross-sectional view taken along line XI-XI′ of FIG. 19.

Initially, as shown in FIGS. 2 and 3, a base substrate BSUB may be prepared, on which transistor layers, emission material layers EMTL, encapsulation layers ENC, touch sensing units and color filter layers are disposed. In other words, one or more transistor layers, one or more emission material layers EMTL, one or more encapsulation layers ENC, one or more touch sensing units, and one or more color filter layers may be disposed on the base substrate BSUB. In the example shown in FIG. 2, nine encapsulation layers ENC are arranged in a matrix on the base substrate BSUB. The base substrate BSUB may be, for example, a mother substrate or a source substrate. The base substrate BSUB the substrate SUB described above may be made of a same material.

Incidentally, as shown in FIG. 2, the base substrate BSUB may include one or more pad areas 900. From the plan view shown in FIG. 2, each of the pad areas 900 may be disposed adjacent to the respective encapsulation layers ENC. For example, each of the pad areas 900 may be disposed adjacent to the respective encapsulation layers ENC in the second direction DR2. In the example shown in FIG. 2, nine pad areas 900 are arranged in a matrix on the base substrate BSUB.

The pad areas 900 may be arranged adjacent to each other in the first direction DR1.

The pad electrodes 700 of the pad areas 900 may be disposed adjacent to each other in the first direction DR1.

Subsequently, as shown in FIGS. 4 and 5, a first mask MK1 may be disposed on the pad areas 900 of the base substrate BSUB in line with the pad areas 900. In other words, the first mask MK1 covering (or overlapping) the pad areas 900 may be disposed on the base substrate BSUB. The first mask MK1 may be attached to the pad areas 900.

According to the embodiment, from the plan view shown in FIG. 4, the first mask MK1 may include one or more first sub-masks SMK1-1, SMK1-2, and SMK1-3 (collectively SMK1) separated from each other. For example, the first mask MK1 may include a (1-1) sub-mask SMK1-1, a (1-2) sub-mask SMK1-2, and a (1-3) sub-mask SMK1-3, as in the example shown in FIG. 4. Each of the first sub-masks SMK1-1, SMK1-2 and SMK1-3 may have a line shape extended in the first direction DR1. The first sub-masks SMK1-1, SMK1-2 and SMK1-3 may be arranged in the second direction DR2. From the plan view perspective, the first sub-mask may be disposed between an edge of the base substrate BSUB and one or more encapsulation layers ENC, or between one or more encapsulation layers ENC adjacent to one another in the second direction DR2.

The first mask MK1 may be implemented as, for example, a tape or a coating layer.

The first mask MK1 may be made of a material containing, for example, an organic material.

Subsequently, as shown in FIGS. 6 and 7, a base reinforcement layer BCPL may be disposed over the first mask MK1 and the encapsulation layers ENC. For example, the base reinforcement layer BCPL may be disposed on the entire surface of the base substrate BSUB including the first mask MK1 and one or more encapsulation layers ENC. To this end, according to an embodiment, a raw material for the base reinforcement layer BCPL, (e.g., an optically transparent resin, or a material containing at least one of epoxy and urethane) may be applied on the base substrate BSUB including the first mask MK1 and one or more encapsulation layers ENC, and then a curing process is carried out on the raw material, such that a base reinforcement layer BCPL may be formed. The curing process may include, for example, at least one of an ultraviolet curing process of irradiating the raw material for the base reinforcement layer BCPL with ultraviolet rays and a thermal curing process of applying heat to the raw material. The base reinforcement layer BCPL and the above-described reinforcement layer CPL may be made of a same material.

The first mask MK1 can prevent the raw material for the base reinforcement layer BCPL from permeating into the pad areas 900 of the base substrate BSUB and the pad electrodes 700 of the pad areas 900.

Subsequently, as shown in FIGS. 8 and 9, a second mask MK2 may be disposed on the base reinforcement layer BCPL. The second mask MK2 may be attached to the base reinforcement layer BCPL. The second mask MK2 may be disposed on the base reinforcement layer BCPL such that it overlaps the encapsulation layers ENC but not with the first mask MK1. For example, the second mask MK2 may be disposed on the base reinforcement layer BCPL such that only the encapsulation layers ENC are selectively hidden (or covered), excluding the first mask MK1. Accordingly, a part of the base reinforcement layer BCPL (hereinafter referred to as a “non-exposed portion”; e.g., a portion of the base reinforcement layer BCPL on the encapsulation layers ENC or a portion of the base reinforcement layer BCPL in contact with the encapsulation layers ENC) is covered by the second mask MK2, while another part of the base reinforcement layer BCPL except for the part (hereinafter referred to as an “exposed portion”; e.g., a portion of the base reinforcement layer BCPL on the first mask MK1 or a portion of the base reinforcement layer BCPL in contact with the first mask MK1 in the third direction DR3) may be exposed to the outside without being covered by the second mask MK2. Herein, the non-exposed portion of the base reinforcement layer BCPL described above may be disposed between the encapsulation layers ENC and the second mask MK2.

According to the embodiment, from the plan view shown in FIG. 8, the second mask MK2 may include second sub-masks SMK2-1, SMK2-2, and SMK2-3 separated from each other. For example, the second mask MK2 may include a (2-1) sub-mask SMK2-1, a (2-2) sub-mask SMK2-2, and a (2-3) sub-mask SMK2-3, as in the example shown in FIG. 8. Each of the second sub-masks SMK2-1, SMK2-2 and SMK2-3 may have a line shape extended in the first direction DR1 to cover the encapsulation layers ENC arranged in the first direction DR1. The second sub-masks SMK2-1, SMK2-2 and SMK2-3 may be arranged in the second direction DR2. From the plan view perspective, the second sub-masks may be disposed between an edge of the base substrate BSUB (or the base reinforcement layer BCPL) and the first sub-masks, or between first sub-masks adjacent to one another in the second direction DR2.

The second mask MK2 may be implemented as a film, for example. According to the embodiment, the second mask MK2 may be an acid-resistant film.

Subsequently, as shown in FIGS. 10 and 11, a process of patterning the base reinforcement layer BCPL may be performed using the second mask MK2. For example, an etching process may be performed to selectively remove exposed portions of the base reinforcement layer BCPL that are not hidden by the second mask MK2.

According to an embodiment of the disclosure, a hydrofluoric acid or non-hydrofluoric acid etchant may be used as an etchant ECT to remove the base reinforcement layer BCPL.

As shown in FIGS. 10 and 11, the etchant ECT may be selectively dropped only onto the exposed portion of the base reinforcement layer BCPL by the second mask MK2.

Then, as shown in FIGS. 12 and 13, the exposed portion of the base reinforcement layer BCPL may be removed by the etchant ECT, such that the first mask MK1 may be exposed to the outside. In other words, the base reinforcement layer BCPL patterned by the etching process may be located between the encapsulation layers ENC and the second mask MK2. From the plan view perspective (e.g., in the plan view shown in FIG. 14), the patterned base reinforcement layer BCPL may be located also between the encapsulation layers ENC adjacent to one another in the first direction DR1 and the second direction DR2. For example, the patterned base reinforcement layer BCPL and the second masks MK2 may have a same line shape.

Incidentally, the first mask MK1 may include a material that does not react with the etchant ECT. Therefore, in case that the base reinforcement layer BCPL is removed by the etchant ECT, the first mask MK1 may not be removed even if the first mask MK1 under the base reinforcement layer BCPL are in contact with the etchant ECT. For example, the first mask MK1 may include a material having a greater etch ratio than the base reinforcement layer BCPL with respect to the etchant ECT. According to an embodiment of the disclosure, in case that the etchant ECT contains a hydrofluoric acid material, the first mask MK1 containing an organic material may not react with the hydrofluoric acid etchant ECT. Accordingly, during the process of etching the base reinforcement layer BCPL, it is possible to prevent the pad electrodes 700 in the pad areas 900 from being damaged by the etchant ECT.

Incidentally, in case that an etchant containing a hydrofluoric acid material is used as the etchant ECT, the base reinforcement layer BCPL may contain hydrofluoric acid. For example, a first side surface S1 of the base reinforcement layer BCPL (or the reinforcement layer CPL of FIG. 1) may include hydrofluoric acid. The first side surface S1 of the base reinforcement layer BCPL (or the reinforcement layer CPL of FIG. 1) may refer to a surface adjacent to the first mask MK1 or the display driver 200 of FIG. 1 described above.

Subsequently, as shown in FIGS. 14 and 15, the first mask MK1 and the second mask MK2 may be removed. For example, the second mask MK2 may be removed, and then the first mask MK1 may be removed. It should be understood, however, that the order in which the first mask MK1 and the second mask MK2 are removed is not limited to this. For example, the first mask MK1 may be removed, and then the second mask MK2 may be removed.

As the first mask MK1 is removed, the pad areas 900 of the base substrate BSUB and the pad electrodes 700 of the pad areas 900 may be exposed to the outside.

In case that the first mask MK1 is implemented as a tape, the first mask MK1 may be physically removed (or separated) from the pad areas 900. For example, the first mask MK1 may be removed (or separated) from the pad areas 900 by a pulling force in the opposite direction to the attachment surface (or adhesive surface). In case that the first mask MK1 is implemented as a coating layer, the first mask MK1 may be chemically removed (or separated) by a solvent-based material. The solvent-based material may include, for example, isopropyl alcohol or acetone.

As the second mask MK2 is removed, the patterned base reinforcement layer BCPL may be exposed to the outside.

In case that the second mask MK2 is implemented as a film, the second mask MK2 may be physically removed (or separated) from the base reinforcement layer BCPL. For example, the second mask MK2 may be removed (or separated) from the base reinforcement layer BCPL by a pulling force in the opposite direction to the attachment surface (or adhesive surface).

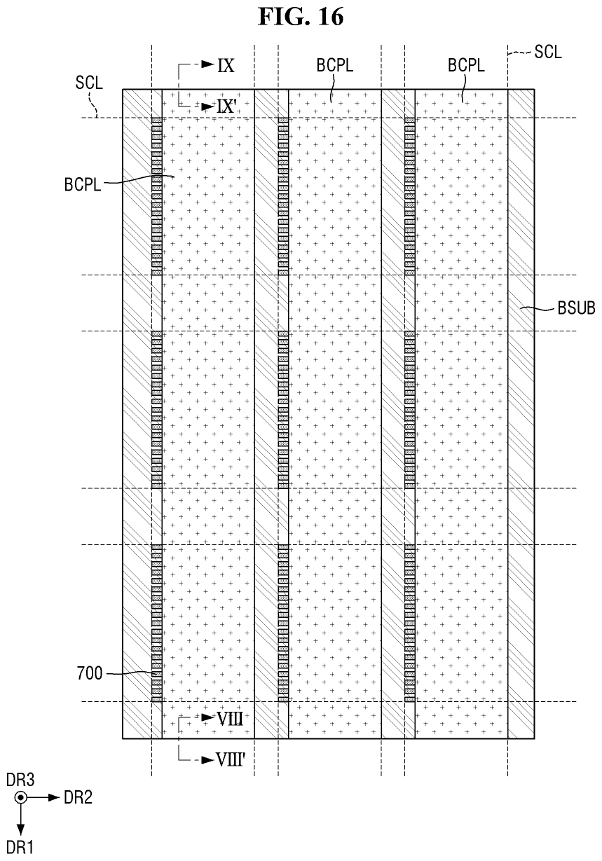

Subsequently, as shown in FIG. 16, the base substrate BSUB may be cut along scribing lines SCL. Accordingly, the base reinforcement layer BCPL on the base substrate BSUB may also be cut along the scribing lines SCL.

One or more display panels 100 may be provided in cell units from the base substrate BSUB via a cutting process. As in the example shown in FIG. 16, nine display panels 100 may be obtained from one base substrate BSUB. FIGS. 17 and 18 show an example of one of the nine display panels 100 separated from the base substrate BSUB. As shown in FIGS. 17 and 18, the display panel 100 may include a substrate SUB separated from the base substrate BSUB, and a reinforcement layer CPL separated from the base reinforcement layer BCPL.

According to an embodiment of the disclosure, the base substrate BSUB may be cut using a wheel or laser beam during the cutting process. While the base substrate BSUB and the base reinforcement layer BCPL are cut by laser beam, at least a part of the cut surface of the base substrate BSUB and at least a part of the cut surface of the base reinforcement layer BCPL cut along the scribing lines SCL may be carbonized. In other words, at least a part of the cut surface of the base substrate BSUB and at least a part of the cut surface of the base reinforcement layer BCPL may each have a carbonization region (or blackened region). For example, as shown in FIG. 18, a second side surface S2 of the reinforcement layer CPL or the base reinforcement layer BCPL may have a carbonization region (or blackened region).

Subsequently, as shown in FIGS. 19 and 20, a functional layer POL may be disposed on the display panel 100. For example, the functional layer POL may be disposed on the reinforcement layer CPL. The functional layer POL may include, for example, a polarizer.

Subsequently, as shown in FIG. 1, the display driver 200 may be disposed in the pad area 900 of the display panel 100.

Subsequently, as shown in FIG. 1, a protective layer 400 may be disposed on the lower surface of the display panel 100 (e.g., the lower surface of the substrate SUB).

Subsequently, as shown in FIG. 1, an end of the intermediate board 600 may be connected to the pad area 900, and the circuit board 300 may be connected to the other end of the intermediate board 600.

Subsequently, as shown in FIG. 1, the intermediate board 600 may be bent such that the circuit board 300 and the protective layer 400 face each other.

Incidentally, since the upper surface of the reinforcement layer CPL (e.g., the surface of the reinforcement layer CPL that faces the functional layer POL) may be flat, the adhesion between the reinforcement layer CPL and the functional layer POL can be improved. Accordingly, as the adhesion between the reinforcement layer CPL and the functional layer POL may be improved, it is possible to prevent the functional layer POL from being separated from the reinforcement layer CPL. Hereinafter, a way how the reinforcement layer CPL (e.g., an upper surface S3 of the reinforcement layer CPL) of the display panel 100 according to an embodiment can be flattened will be described in detail with reference to FIGS. 16, 21, and 22.

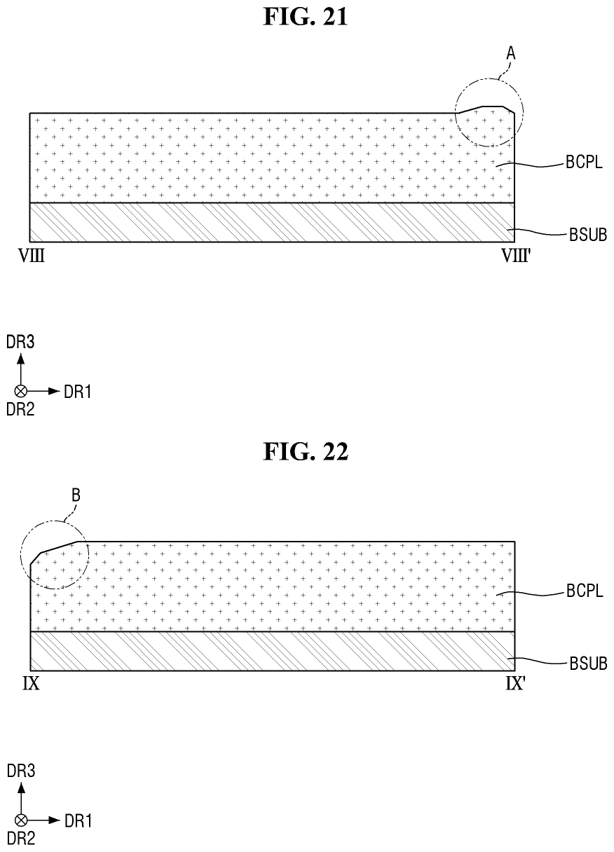

FIG. 21 is a schematic cross-sectional view taken along line VIII-VIII′ of FIG. 16. FIG. 22 is a cross-sectional view taken along line IX-IX′ of FIG. 16.

According to a method of fabricating a display device according to an embodiment, since a cutting process (e.g., the process shown in FIG. 16) is carried out after the base reinforcement layer BCPL has been formed on the base substrate BSUB, a non-flat portion of the base reinforcement layer BCPL may be formed at an edge of the base substrate BSUB rather than the display panel 100. This will be described in more detail as follows:

The raw material for the base reinforcement layer BCPL may be applied on the encapsulation layer ENC by slit coating. For example, a slit coating device may discharge a raw material through a nozzle while moving from an edge of the base substrate BSUB to the opposite edge of the base substrate BSUB to apply the raw material onto the entire surface of the base substrate BSUB. In doing so, due to the nature of the slit coating device, the raw material first discharged and the raw material last discharged from the nozzle of the slit coating device may be raised or depressed in the third direction DR3 than other portions at the edges of the base substrate BSUB, as shown as portion A of FIG. 21 or portion B of FIG. 22. In other words, as the nozzle of the slit coating device is located at an edge of the base substrate BSUB at the time of first discharging by the slit coating device while the nozzle of the slit coating device is located at the opposite edge of the base substrate BSUB at the time of final discharging by of the slit coating device, the base reinforcement layer BCPL may have a bump shape shown as portion A of FIG. 21 or a slope shape shown as portion B of FIG. 22.

However, the above-described bump shape and slope shape may be formed at the portions discarded from the base substrate BSUB after the cutting process, and thus they may not have any effect on the display panel 100 separated from the base substrate BSUB after the cutting process. Accordingly, the reinforcement layer CPL of the display panel 100 separated from the base substrate BSUB after the cutting process may have a flat surface. In other words, the upper surface S3 of the reinforcement layer CPL of the display panel 100 may have a flat surface. Therefore, in the display device according to the embodiment, the adhesion between the functional layer POL and the reinforcement layer CPL can be improved. In the method according to the embodiment of the disclosure, a base reinforcement layer BCPL is formed on the entire surface of the base substrate BSUB and then the base substrate BSUB is cut, so that a display device can be fabricated faster compared to a process of forming a reinforcement layer CPL for each display panel 100 after the cutting process.

On the other hand, in case that a process of cutting the base substrate BSUB is performed and then a process of forming the reinforcement layer CPL for each display panel 100 is performed individually, the reinforcement layer CPL at an edge and the opposite edge of the display panel 100 may not be flat due to the nature of the slit coating device. Accordingly, such a method may be inefficient, and the adhesion between the reinforcing layer CPL and the functional layer POL may be weakened, which may cause the functional layer POL to be separated from the reinforcement layer CPL.

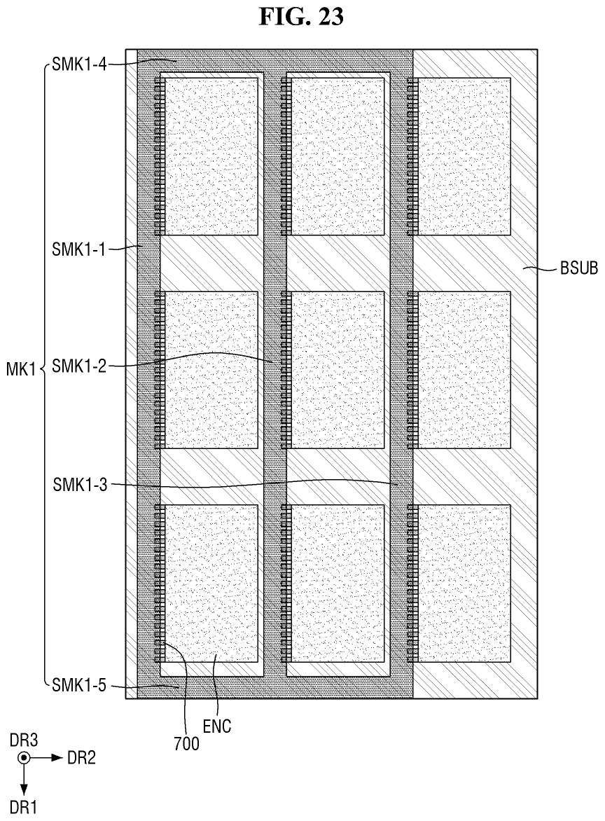

FIG. 23 is a schematic view for illustrating a method of fabricating a display device according to an embodiment of the disclosure.

A method of fabricating a display device of FIG. 23 may be different from the method of fabricating a display device of FIG. 4 at least in the configuration of a first mask MK1, and the description will focus on the difference.

The first mask MK1 of FIG. 23 may further include a (1-4) sub-mask SMK1-4 and a (1-5) sub-mask SMK1-5 in addition to the (1-1) to (1-3) sub-masks SMK1-1 to SMK1-3 described above.

The (1-1) to (1-5) sub-masks SMK1-1 to SMK1-5 may be formed integrally or integral with each other.

The (1-4) sub-mask SMK1-4 may be extended in a direction (e.g., the second direction DR2) that intersects the direction in which the (1-1) to (1-3) sub-masks SMK1-1 to SMK1-3 are extended (e.g., the first direction DR1). The (1-4) sub-mask SMK1-4 may connect ends of the (1-1) to (1-3) sub-masks SMK1-1 to SMK1-3 with one another.

The (1-5) sub-mask SMK1-5 may be extended in a direction (e.g., the second direction DR2) that intersects the direction in which the (1-1) to (1-3) sub-masks SMK1-1 to SMK1-3 are extended (e.g., the first direction DR1). The (1-5) sub-mask SMK1-5 may connect the other ends of the (1-1) to (1-3) sub-masks SMK1-1 to SMK1-3 with one another.

As the first mask MK1 of FIG. 23 may include the first sub-masks SMK1-1 to SMK1-5 integrally formed, the first mask MK1 can be removed more easily.

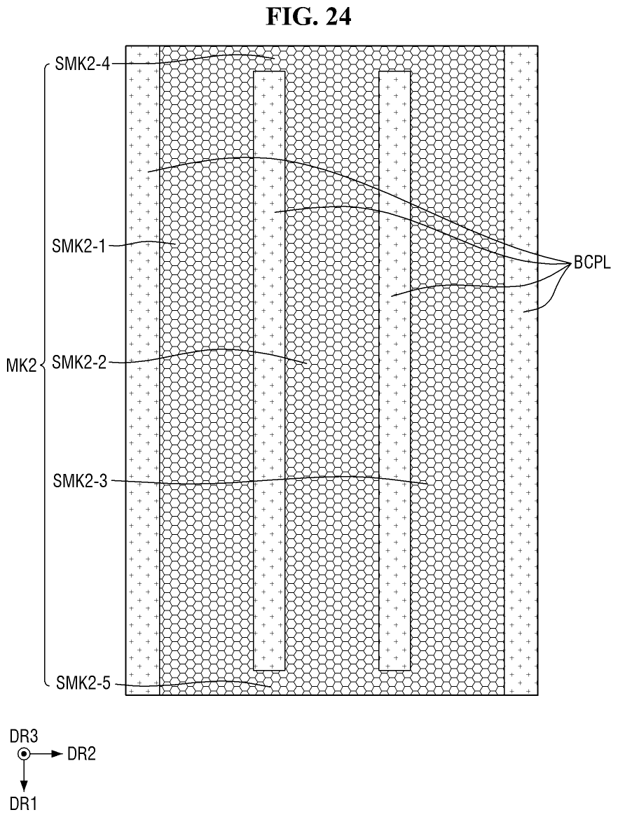

FIG. 24 is a schematic view for illustrating a method of fabricating a display device according to an embodiment of the disclosure.

A method of fabricating a display device of FIG. 24 may be different from the method of fabricating a display device of FIG. 8 at least in the configuration of a second mask MK2, and the description will focus on the difference.

The second mask MK2 of FIG. 24 may further include a (2-4) sub-mask SMK2-4 and a (2-5) sub-mask SMK2-5 in addition to the (2-1) to (2-3) sub-masks SMK2-1 to SMK2-3 described above.

The (2-1) to (2-5) sub-masks SMK2-1 to SMK2-5 may be formed integrally or integral with each other.

The (2-4) sub-mask SMK2-4 may be extended in a direction (e.g., the second direction DR2) that intersects the direction in which the (2-1) to (2-3) sub-masks SMK2-1 to SMK2-3 are extended (e.g., the first direction DR1). The (2-4) sub-mask SMK2-4 may connect ends of the (2-1) to (2-3) sub-masks SMK2-1 to SMK2-3 with one another.

The (2-5) sub-mask SMK2-5 may be extended in a direction (e.g., the second direction DR2) that intersects the direction in which the (2-1) to (2-3) sub-masks SMK2-1 to SMK2-3 are extended (e.g., the first direction DR1). The (2-5) sub-mask SMK2-5 may connect opposite ends of the (2-1) to (2-3) sub-masks SMK2-1 to SMK2-3 with one another.

As the second mask MK2 of FIG. 24 may include the second sub-masks SMK2-1 to SMK2-5 integrally formed, the second mask MK2 can be removed more easily.

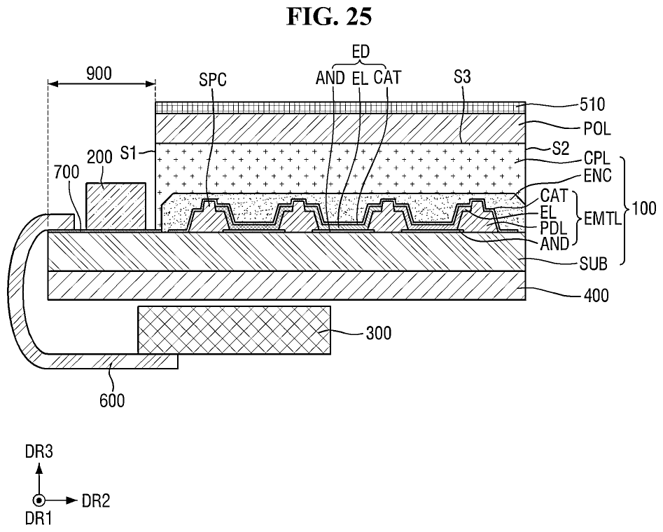

FIG. 25 is a schematic cross-sectional view of a display device according to the embodiment of the disclosure.

A display device of FIG. 25 may be different from the display device of FIG. 1 described above at least in that the former further includes an auxiliary functional layer 510.

The display device of FIG. 25 may further include the auxiliary functional layer 510 disposed on the functional layer POL.

The auxiliary functional layer 510 may include, for example, at least one of an anti-fingerprint layer, an anti-reflection layer, and a hard coating layer.

The anti-fingerprint layer can prevent fingerprints on the display panel 100.

The anti-reflection layer can reduce reflection caused by light incident from the outside of the display panel 100.

The hard coating layer can prevent surface damage (e.g., scratches) of the display panel.

The method of fabricating the display device of FIG. 25 may further include disposing the auxiliary functional layer 510 on the functional layer POL after the functional layer POL is disposed.

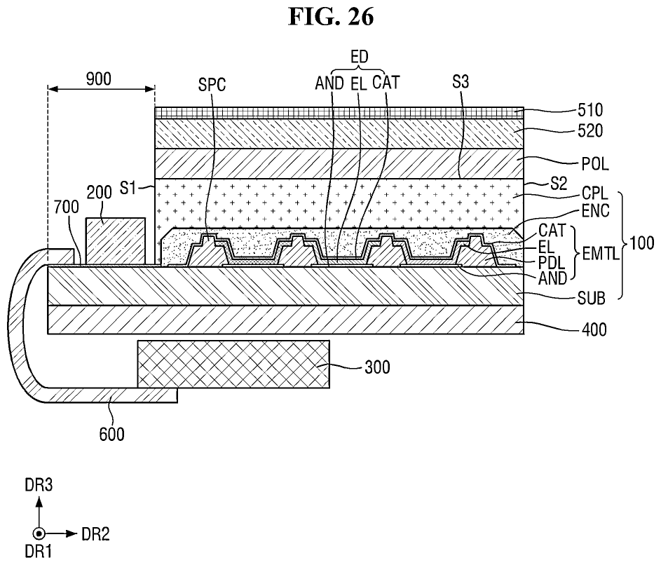

FIG. 26 is a schematic cross-sectional view of a display device according to an embodiment of the disclosure.

A display device of FIG. 26 may be different from the display device of FIG. 25 described above at least in that the former further includes a window layer 520.

The display device of FIG. 26 may further include the window layer 520 disposed between the functional layer POL and the auxiliary functional layer 510.

The window layer 520 may include a transparent resin. The window layer 520 can improve the strength of the display panel 100.

The auxiliary functional layer 510 may include, for example, at least one of an anti-fingerprint layer, an anti-reflection layer, and a hard coating layer.

The method of fabricating the display device of FIG. 26 may further include disposing the window layer 520 on the functional layer POL after the functional layer POL has been disposed, and disposing the auxiliary functional layer 510 on the window layer 520.

The above description is an example of technical features of the disclosure, and those skilled in the art to which the disclosure pertains will be able to make various modifications and variations. Thus, the embodiments of the disclosure described above may be implemented separately or in combination with each other.

The embodiments disclosed in the disclosure are intended not to limit the technical spirit of the disclosure but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a substrate;
a first electrode on the substrate;
a pixel-defining layer on the first electrode;
an emissive layer on the first electrode and the pixel-defining layer;
a second electrode on the emissive layer;
an encapsulation layer on the second electrode;
a functional layer on the encapsulation layer; and
a reinforcement layer between the encapsulation layer and the functional layer,
wherein an interface between the reinforcement layer and the functional layer is substantially flat.

2. The display device of claim 1, wherein the reinforcement layer contains hydrofluoric acid.

3. The display device of claim 2, wherein a first side surface of the reinforcement layer contains the hydrofluoric acid.

4. The display device of claim 3, further comprising:
a display driver disposed in a pad area on the substrate.

5. The display device of claim 4, wherein the first side surface of the reinforcement layer is adjacent to the display driver.

6. The display device of claim 3, wherein a second side surface of the reinforcement layer located opposite to the first side surface of the reinforcement layer comprises a carbonization region.

7. The display device of claim 1, wherein the reinforcement layer is made of a material containing at least one of an optically transparent resin, epoxy, and urethane.

8. The display device of claim 1, wherein the functional layer comprises a polarizer.

9. The display device of claim 1, further comprising:
an auxiliary functional layer on the functional layer.

10. The display device of claim 9, wherein the auxiliary functional layer comprises at least one of an anti-fingerprint layer, an anti-reflection layer, and a hard coating layer.

11. The display device of claim 9, further comprising:
a window layer between the functional layer and the auxiliary functional layer.

12. The display device of claim 1, further comprising:
an intermediate board connected to a pad area of the substrate.

13. The display device of claim 12, further comprising:
a circuit board connected to the intermediate board.

14. The display device of claim 1, further comprising:
a protective layer disposed under the substrate.

15. A method of fabricating a display device, the method comprising:
disposing an encapsulation layer on a base substrate;
disposing a first mask on a pad area of the base substrate to cover the pad area;
disposing a base reinforcement layer on an entire surface of the base substrate comprising the encapsulation layer and the first mask;
disposing a second mask on the base reinforcement layer in line with the encapsulation layer;
patterning the base reinforcement layer by selectively removing a portion of the base reinforcement layer exposed by the second mask;
removing the first mask and the second mask; and
cutting the base substrate and the base reinforcement layer along a scribing line to form a display panel comprising a substrate and a reinforcement layer.

16. The method of claim 15, wherein the patterning of the base reinforcement layer by selectively removing the portion of the base reinforcement layer exposed by the second mask comprises selectively removing the portion of the base reinforcement layer to expose the first mask.

17. The method of claim 15, wherein the patterning of the base reinforcement layer by selectively removing the portion of the base reinforcement layer exposed by the second mask comprises etching the base reinforcement layer using an etchant.

18. The method of claim 17, wherein the etchant contains hydrofluoric acid.

19. The method of claim 15, wherein the cutting of the base substrate and the base reinforcement layer along the scribing line comprises cutting the base substrate and the base reinforcement layer using laser beam.

20. The method of claim 15, further comprising:
disposing a functional layer on the reinforcement layer of the display panel.

21. The method of claim 20, wherein the functional layer comprises a polarizer.

22. The method of claim 20, further comprising:
disposing an auxiliary functional layer on the functional layer.

23. The method of claim 22, wherein the auxiliary functional layer comprises at least one of an anti-fingerprint layer, an anti-reflection layer, and a hard coating layer.

24. The method of claim 22, further comprising:
disposing a window layer between the functional layer and the auxiliary functional layer.
